(19) United States
(12) Patent Application Publication
(10) Pub. No.: US 2005/0118833 A1
(43) Pub. Date: Jun. 2, 2005

(54) Method for manufacturing semiconductor device

(75) Inventors: Kazumasa Mitsumune, Kurashiki-shi (JP); Tsukasa Doi, Fukuyama-shi (JP); Yushi Inoue, Fukuyama-shi (JP); Kenichirou Abe, Fukuyama-shi (JP); Takanori Sonoda, Fukuyama-shi (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha, Osaka (JP)

(21) Appl. No.: 10/998,782

(22) Filed: Nov. 30, 2004

(30) Foreign Application Priority Data
Dec. 1, 2003 (JP) 2003-401770
Mar. 31, 2004 (JP) 2004-105900

(51) Int. Cl. H01L 21/31; H01L 21/469

(52) U.S. Cl. 438/758

(57) ABSTRACT

It is an object of the present invention to provide a method for manufacturing a semiconductor device suppressing the occurrence of voids in an insulating film.

A method for manufacturing a semiconductor device according to the present invention comprises the steps of: (1) forming an insulating film 11 composed of a thin silicon nitride film on a semiconductor substrate 1 having at least a necessary element and a recessed part 6 so as to cover the recessed part 6; (2) modifying the surface of the insulating film 11; and (3) forming a BPSG film 15 as an interlayer insulation film on the insulating film. The occurrence of voids in the interlayer insulation film 15 is suppressed by the process for modifying the surface.

### CROSS-REFERENCE TO RELATED APPLICATION

This application is related to Japanese applications No. 2003-401770 filed on Dec. 1, 2003, and No. 2004-105900 filed on Mar. 31, 2004 whose priorities are claimed under 35 USC §119, the disclosures of which are incorporated by reference in their entirety.

### BACKGROUND OF THE INVENTION

1. Field of the Invention

The invention relates to a method for manufacturing a semiconductor device, and more particularly to a method for forming an interlayer insulation film.

2. Description of Related Art

A technique in which a step of a high aspect ratio is embedded and flattened by an interlayer insulation film formed at low temperature has increasingly been raised in importance along with enhancement of density and integration of LSI.

FIG. 3 is a process sectional view showing a conventional method for manufacturing a semiconductor device. Hereinafter, a method for manufacturing a conventional semiconductor device will be described by using FIG. 3.

First, a gate insulating film 53a and a polysilicon film 53b are deposited on a semiconductor substrate 51, and a gate pattern 53 is formed by patterning. Next, sidewalls 55 are formed on the side surfaces of the gate pattern 53, and a structure shown in FIG. 3(a) is obtained. At this time, recessed parts 56 are formed between the gate patterns 53.

Next, source/drain regions 57 are formed by performing impurity ion implantation in a self-aligning manner to the sidewalls 55. A silicon nitride film (SiN film) 59 used as a stopper film when contact openings are formed is formed thereon, obtaining a structure shown in FIG. 3(b).

Next, for instance, an interlayer insulation film 61 composed by a BPSG film is deposited at about 400 to about 500° C. by a SiH₄-O₂-base atmospheric pressure CVD method or a TEOS-O₃-base CVD method, obtaining a structure shown in FIG. 3(c).

When the BPSG film 61 is deposited by the CVD method, the coverage of the BPSG film 61 is inferior in the recessed part 56 between the gates or the like, and the BPSG film 61 is formed in an overhanging shape. Thereby, voids 65 may be produced.

FIG. 4 is a plan view of the semiconductor substrate 51 on which an element is formed. Problems when the voids 65 are produced will be described by using FIG. 4.

After the processes above, tungsten plugs 67 are usually formed arranged in parallel in the longitudinal direction of the gate pattern 53 in the recessed parts 56 between the gate patterns 53. Since the voids 65 are also formed in parallel in the longitudinal direction of the gate pattern 53, a problem occurs in that when the tungsten plugs 67 are formed by a CVD method or the like, tungsten enters into inside of the voids 65 and the adjacent tungsten plugs 67 are electrically connected.

The voids 65 are usually quenched by performing reflow of the BPSG film 61 by a heat processing in a furnace of about 850° C. or lamp annealing of about 1000° C.

However, along with further miniaturization of a device, when the interlayer insulation film 61 is formed by embedding the above-mentioned BPSG film in a region between gates having a step of a narrower pitch interval (for instance, the pitch being narrower than a gate space of 0.3 μm: the space being 0.2 μm or less after forming the sidewalls) and a high aspect ratio (for instance, an aspect ratio above 3), the coverage immediately after the film formation becomes worse, and the voids 65 caused after the film formation become larger. A furnace processing of at least 850° C. for about 15 minutes or a lamp annealing at 1000° C. for about 30 seconds is required as a reflow processing after the film formation so as to quench the voids 65. However, a demand for lowering a process temperature becomes more severe along with miniaturization of a device. When the heat processing of 800° C. or higher is performed in a device of 0.18 μm or less, a problem occurs in that transistor characteristics such as suppression of short channel effect and driving current cannot be sufficiently secured. Therefore, a high temperature annealing condition cannot be used.

A method for forming the BPSG film by a twice divided process is disclosed as a conventional method for solving such a problem (for instance, refer to Japanese Unexamined Patent Publication No. 2001-345322). In this method, first, a first BPSG film is formed, and unevenness of the surface is then improved by applying a first heat processing. Next, a second BPSG film is formed, and a second heat processing is then applied.

However, when the BPSG film is formed by a twice divided process, an interface between an upper BPSG film and a lower BPSG film is exposed in a contact forming process or an interlayer CMP process as a post processing, and an abnormal shape may be produced from an etch speed difference of a wet processing due to a difference between characteristics of the upper BPSG film and that of the lower BPSG film.

Also, a method for performing a reflow processing at low temperature by improving impurity concentration of the BPSG film is known.

When the impurity concentration of the BPSG film is improved, a temperature of a reflow processing can be lowered. However, since shrink fastening is insufficient, the film is not compact and becomes unstable.

Thus, it is difficult to form an excellent interlayer insulation film in which voids do not remain without damaging reliability of a device.

### SUMMARY OF THE INVENTION

The present invention has been accomplished in view of the foregoing. It is an object of the present invention to provide a method for manufacturing a semiconductor device suppressing the occurrence of voids in the interlayer insulation film.

A method for manufacturing a semiconductor device of the present invention, comprising the steps of:
(1) forming a thin insulating film on a semiconductor substrate having at least a necessary element and a recessed part so as to cover the recessed part;
(2) modifying the surface of the insulating film; and
(3) forming an interlayer insulation film on the insulating film.

According to the method for manufacturing the semiconductor device of the present invention, the coverage of the interlayer insulation film is improved, because the interlayer insulation film is formed after the surface of the insulating film is modified. Therefore, the interlayer insulation film is not likely to be formed in an overhanging shape, and the occurrence of voids in the interlayer insulation film can be suppressed. Therefore, according to the method for manufacturing of the present invention, the semiconductor device in which the occurrence of voids is suppressed can be manufactured.

Also, according to the present invention method, the semiconductor device of which the width of the recessed part is narrower than that of the conventional recessed part and the aspect ratio is larger can be manufactured.

### BRIEF DESCRIPTION OF THE DRAWINGS

FIG. 1 is a process sectional view showing a method for manufacturing a semiconductor device according to Example 1 of the present invention.

FIG. 2 is a graph showing the relationship between the embedding aspect ratio and the occurrence rate of voids produced in a BPSG film 15 in a semiconductor device subjected to various surface treatments in Example 1 of the present invention.

FIG. 3 is a process sectional view showing a conventional method for manufacturing a semiconductor device.

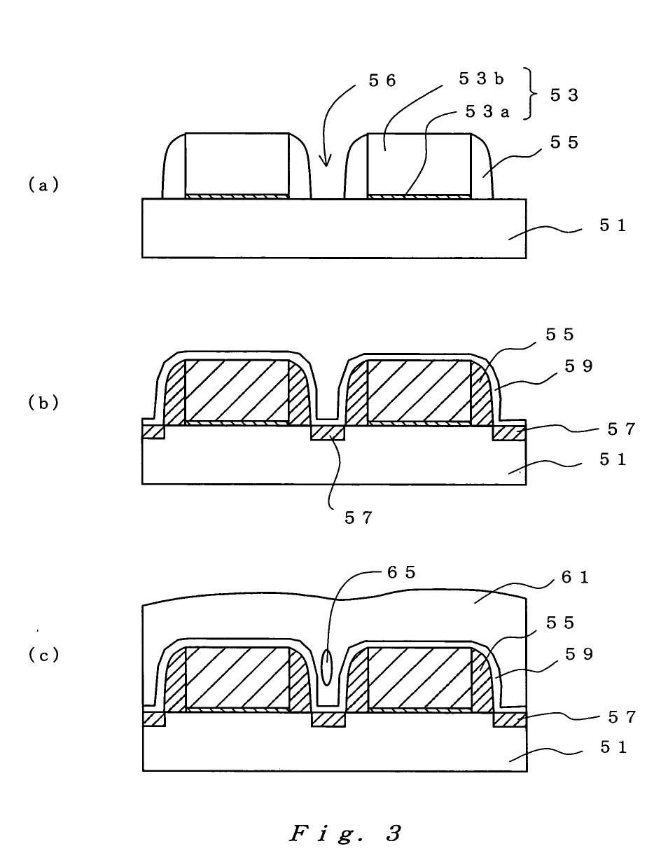

FIG. 4 is a plan view of a semiconductor substrate used for explaining problems when voids are produced in a conventional method for manufacturing a semiconductor device.

### DESCRIPTION OF THE PREFERRED EMBODIMENTS

The method for manufacturing the semiconductor device of the present invention, comprising the steps of:
(1) forming a thin insulating film on the semiconductor substrate having at least the necessary element and the recessed part so as to cover the recessed part;
(2) modifying the surface of the insulating film; and
(3) forming the interlayer insulation film on the insulating film.

First, the step (1), that is, the process for forming the thin insulating film on the semiconductor substrate having at least the necessary element and the recessed part so as to cover the recessed part will be described.

In this specification, “on the semiconductor substrate” includes “contact with the semiconductor substrate,” “contact with the semiconductor substrate via a protection film and an insulating film or the like,” or “noncontact with the semiconductor substrate above the semiconductor substrate.” Also, “on the other film” and “on the layer” or the like are the same.

For instance, element semiconductor substrates such as Si and Ge, and compound semiconductor substrates such as GaAs, GaN, GaP, InP, ZnO and ZnSe can be used for the semiconductor substrate. These may be a monocrystalline or a polycrystal. The semiconductor substrate may be an n-type or a p-type doped semiconductor substrate, and an n-type or a p-type well may be formed in the area where the semiconductor device is formed. Particularly, it is preferable to use a p-type silicon monocrystalline substrate.

An “element” means a semiconductor element such as FET, DRAM, a nonvolatile memory or the like.

The recessed part means, for instance, an area formed between two adjoining gate patterns extending mutually in parallel. The recessed part is made deeper by increasing the height of the gate pattern from the substrate, and the deeper the depth of the recessed part is, the more easily voids are produced. Thereby, the present invention is suitably used for manufacturing a nonvolatile semiconductor memory device having a two stage gate electrode and having a deep recessed part, for instance.

A silicon nitride film or the like can be used for the insulating film. However, insulating films formed by other materials such as a silicon oxide film or the like may be used as long as the surface of the insulating film can be modified and the insulating film can improve the coverage of the interlayer insulation film as described below. The film thickness of the insulating film is usually thinner than that of the interlayer insulation film, and for instance, is within the range of 10 to 50 nm, and preferably about 30 nm.

For the insulating film, it is preferable to use a film which becomes an etching stopper film, that is, a film formed by a material having a small etching selectivity to the interlayer insulation film in a process for forming contact openings as a post process.

The insulating film may be formed by a low pressure thermal CVD method or a plasma CVD method or the like at a temperature of 450° C. to 700° C., and preferably 550 to 600° C. The reason is that because Co or Ni salicide is formed on a Si substrate, fluctuation in device (salicide) characteristics is produced when the film is formed at a temperature as high as 600° C. or higher.

Next, the step (2), that is, a process for modifying the surface of the insulating film will be described.

“Modifying the surface of the insulating film” includes oxidizing the surface of the insulating film, forming minute irregularities in the surface of the insulating film, and making the surface of the insulating film a chemically active state. The interlayer insulation film can be stably formed on the insulating film in this state, and the coverage of the interlayer insulation film to the recessed part can be improved. In addition, the occurrence of voids in the interlayer insulation film can be suppressed.

For instance, examples of the methods include the following four kinds.

A first method oxidizes the surface of the insulating film in an 02 atmosphere. At this time, the temperature may be within the range of 650 to 790° C., and more preferably about 700° C. The flow rate of O₂ gas may be within the range of 5 to 20 L/minute, and more preferably 5 to 15 L/minute. The oxidizing time may be within the range of 5 to 60 minutes, and more preferably 15 to 30 minutes. A process at low temperature cannot achieve the effect sufficiently for modifying the surface, and a process at a temperature as high as 800° C. or higher could cause fluctuation in the device characteristics.

A second method oxidizes the surface of the insulating film by a plasma processing in an O₂ or an N₂O atmosphere. O₂ and N₂O may be individually used or the mixed gas thereof may be used. At this time, the flow rate may be within the range of 500 to 5000 sccm, and preferably about 1500 sccm. At this time, the output may be within the range of 500 to 3000 W, and preferably about 1500 W. At this time, the pressure may be within the range of 0.1 to 1000 mTorr, and preferably about 800 mTorr. At this time, the temperature may be within the range of 300 to 550° C., and preferably 400 to 450° C.

A third method oxidizes the surface of the insulating film in an 03 atmosphere. At this time, the temperature may be within the range of 250 to 450° C., and preferably about 400° C. The flow rate of the O₃ (O₂/O₃) gas may be within the range of 2 to 10 L/minute, and preferably 4 to 8 L/minute. The concentration of O₃ may be within the range of 5 to 20 wt %, and preferably 12 to 17 wt %. The oxidizing time may be within the range of 1 to 10 minutes, and preferably 2 to 3 minutes.

A fourth method oxidizes the surface of the silicon nitride film by a liquid chemical processing. A liquid mixture composed of sulfuric acid and hydrogen peroxide water, and ozone water or the like can be used for the liquid chemical.

The temperature at the time of the processing by the liquid mixture composed of sulfuric acid and hydrogen peroxide water may be within the range of 100 to 150° C., and preferably 120 to 150° C. The processing time may be within the range of 5 to 60 minutes, and preferably 5 to 20 minutes. In the case of the processing by ozone water, the processing at room temperature is preferable.

These methods may be used individually or in combination. For instance, after the plasma processing is performed, the liquid chemical processing can be performed. The surface of the insulating film can be modified by either of the above methods so that an oxidizing atmosphere or the like is formed on the surface, and the interlayer insulation film can be stably formed on the insulating film.

Next, the step (3), that is, a process for forming the interlayer insulation film on the insulating film will be described.

The interlayer insulation film may be composed of a BPSG film. This film may be formed by a known CVD method such as a TEOS-O₃-base CVD method. The thickness of the BPSG film as the interlayer insulation film may be within the range of 500 to 1500 nm, and more preferably 700 to 1200 nm.

The BPSG film may have the concentration of boron of 3.5 to 7.0 wt %, and more preferably about 4.0 to about 6.0 wt %. The concentration of phosphorus may be within the range of 3.5 to 6.0 wt %, and the total concentration of impurity is more preferably within the range of about 8.0 to about 10.0 wt %. The growth temperature may be within the range of 350 to 600° C., and more preferably about 400 to about 500° C. The reason is that the increase in concentration of boron causes the increase in hygroscopicity of the film and the noncompact film quality. This can cause deposition of impurities and poor quality of the film, and therefore post processes cannot be suitably performed. A reflow effect cannot be sufficiently achieved at a temperature of 790° C. or lower.

A process for performing reflow of the interlayer insulation film by a heat processing may be further provided after step (3). When voids are produced, the voids can be quenched by performing reflow of the interlayer insulation film. A seam formed at the vicinity of the center of the recessed part can be bonded by performing reflow of the interlayer insulation film. According to the method of the present invention, even if voids are generated, the size of the voids is smaller than that of the voids produced by a conventional method, and thereby, the voids can be quenched by performing reflow at relatively low temperature in a short period of time.

Preferably, the heat processing is a furnace processing in an N₂ atmosphere of the temperature condition of 700° C. to 790° C., and preferably 750° C. to 790° C., or is a furnace processing in a water vapor atmosphere of a temperature condition of 700° C. to 790° C., and preferably 700° C. to 750° C. The reason is that the densification of the BPSG film is insufficient when the temperature condition is not higher than 700° C., and though the heat tolerance of the semiconductor element is decreased as the semiconductor element is made minute, the semiconductor element is not easily damaged in the reflow at a temperature of 790° C. or lower.

### EXAMPLE 1

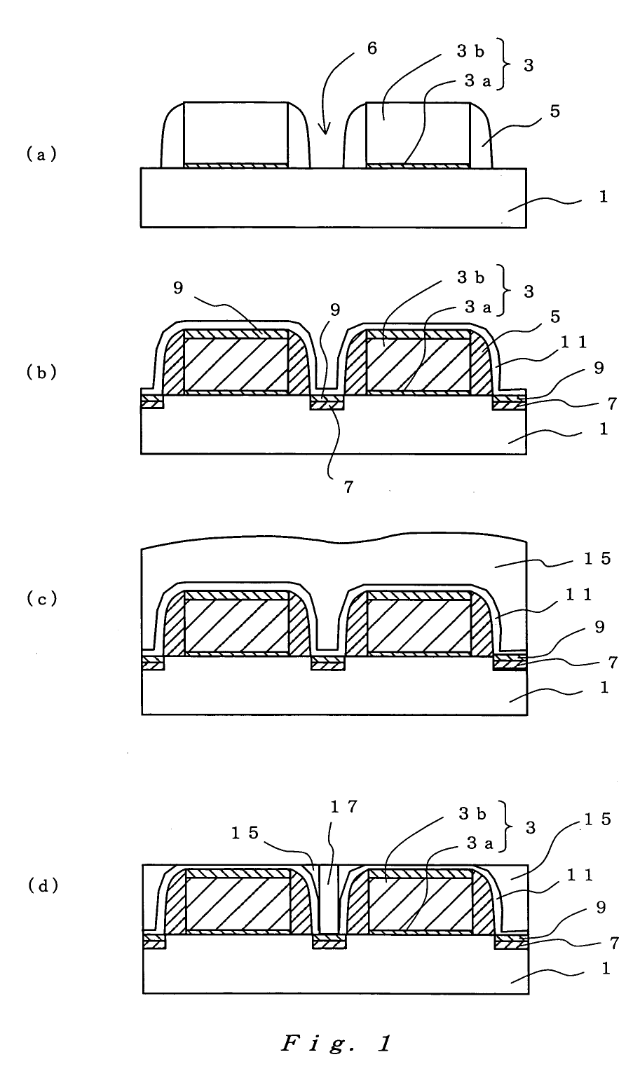

FIG. 1 is a process sectional view showing a method for manufacturing a semiconductor device according to Example 1 of the present invention. Hereinafter, the method for manufacturing the semiconductor device according to the Example will be described with reference to FIG. 1.

First, a polysilicon film 3b is formed via a gate insulating film 3a on a semiconductor substrate 1. The polysilicon film 3b is then patterned to form a gate pattern 3. Next, a silicon oxide film or a silicon nitride film is formed on the entire surface of the substrate 1 so as to cover the gate pattern 3, and is etched back and removed using dry etching. Sidewalls 5 are then formed at the sidewalls of the gate pattern 3 by the residual silicon oxide film or silicon nitride film, obtaining a structure shown in FIG. 1(a). At this time, the recessed parts 6 are formed between the gate patterns 3.

Next, source/drain regions 7 are formed in a self-aligning manner using the gate patterns 3 and the side walls 5 as a mask by a known method, and a cobalt salicide (CoSi) film 9 is selectively formed on the surface of the region 7 and gate pattern 3 in a self-aligning manner by a known method.

Next, a silicon nitride film 11 having a film thickness of 50 nm is formed on the entire surface under the following conditions by a low pressure thermal CVD method, obtaining a structure shown in FIG. 1(b). The film 11 is used as a stopper film in a process for forming contact openings, which is a post process,
Temperature/pressure/: 700° C./275 Torr
Usage gas: SiH₄/NH₃=20/2000 sccm
Film deposition speed: 15 nm/minute
Film thickness: 50 nm

The silicon nitride film 11 may be formed under the following conditions by using a plasma CVD device.
Temperature/pressure/: 550° C./4.2 Torr
Usage gas: SiH₄/NH₃/N₂=200/80/4000 sccm
RF Power: 930 W
Film deposition speed: 100 nm/minute
Film thickness: 50 nm

Next, the surface of the silicon nitride film 11 is modified by any of the following methods.

(1) The surface of the silicon nitride film 11 is oxidized in an O₂ atmosphere in a diffusion furnace.
Temperature: 700° C.
Gas: O₂ 5 to 15 L/minute
Time: 15 to 60 minutes

(2) The surface of the silicon nitride film 11 is modified by forming plasma in an O₂ or an N₂O atmosphere.
O₂ flow rate: 1500 sccm
PR Power: 1500 W
Pressure: 800 mTorr
Time: 15 minutes
Temperature: 300 to 450° C.

(3) The surface of the silicon nitride film 11 is modified in an 03 atmosphere.
O₃/O₂ flow rate: 4000 sccm
Concentration of O₃: 12 to 17 wt %
Temperature: 300 to 400° C.
Time: 2 minutes
Pressure: 200 to 600 Torr

(4) The surface of the silicon nitride film 11 is oxidized by a liquid chemical processing.

SPM Washing (Liquid Mixture Composed of Sulfuric Acid and Hydrogen Peroxide Water)

Temperature: 120 to 150° C.
Time: 5 to 20 minutes

It is also possible to combine the above techniques (for instance, the liquid chemical washing process is performed after the plasma processing).

Next, a BPSG film 15 having a thickness of 700 to 1200 nm is formed in the recessed parts 6 having a depth of 200 to 350 nm formed between the gate patterns 3. In this growth condition, TEOS/TEP/TEOB is set to 600/195/47 mgm, and 03/He is set to 4000/6000 sccm. The growth pressure is set to 200 Torr, the growth temperature is set to 480° C. In addition, the concentration of boron (B) is set to 4.0 wt %, and the concentration of phosphorus (P) is set to 5.0 wt %. The growth speed is 350 nm/minute in this condition.

Since the surface of the silicon nitride film 11 is in the oxidizing atmosphere in the initial film deposition stage of the BPSG film 15 by the above surface processing, a film having excellent coverage is stably formed.

No voids are produced in the BPSG film 15 formed thus, or the size of the voids is smaller than that of the voids according to the conventional method even if the voids are produced. The voids produced are quenched by a reflow heating processing in an N₂ atmosphere at 770° C. for 30 minutes by using a furnace, and thereby a structure shown in FIG. 1(c) is obtained.

The BPSG film 15 may be previously annealed in a water vapor atmosphere at 700° C., and in this case, the reflow processing of the BPSG film 15 can be performed at lower temperature.

The BPSG film 15 is then flattened using a CMP method, and contact openings are formed in the recessed parts 6 between the respective gate patterns 3. Tungsten plugs 17 are then formed by embedding tungsten in the openings by a CVD method, and thereby a structure shown in FIG. 1(d) is obtained.

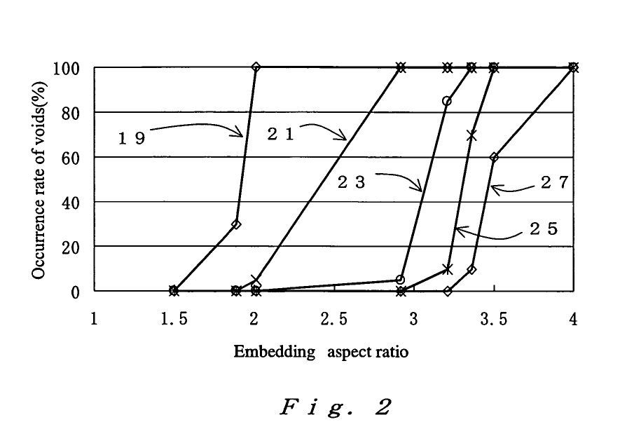

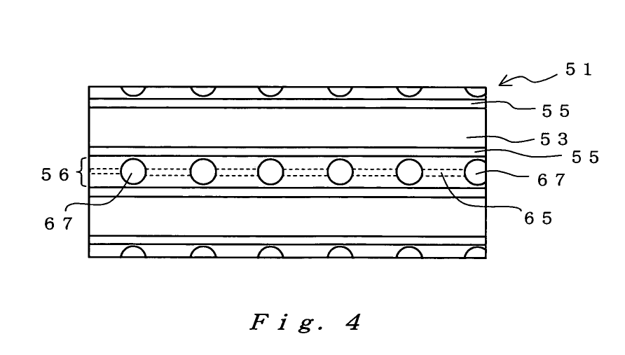

FIG. 2 is a graph showing the relationship between the embedding aspect ratio and the occurrence rate of voids produced in a BPSG film 15 in a semiconductor device subjected to various surface treatments in the conditions shown in the above Example. Herein, the occurrence rate of the voids is calculated from the ratio where the short-circuit is produced between two adjoining tungsten plugs 17 (arranged in the direction perpendicular to this paper plane in FIG. 1(d)) formed in the recessed parts 6 between the respective gate patterns 3 (see FIG. 4). The interval between the gates is set to 0.3 μm, and the contact diameter is set to 0.15 to 0.18 μm.

Numeral 19 designates the result when the surface processing is not performed, and numeral 21 designates the result when the SPM is performed. Numeral 23 designates the result when the processing is performed by the O₂ plasma, and numeral 25 designates the result when the SPM washing is performed after the processing is performed by the O₂ plasma. Numeral 27 designates the result when the O₂ oxidization is performed by the diffusion furnace.

As is apparent from FIG. 2, it is shown that the lower occurrence rate of the voids is shown in the high embedding aspect ratio than the case that the surface processing is not performed, and the occurrence of the voids is suppressed by the surface processing even when any surface processing is performed.

FIG. 2 shows that particularly, the occurrence rate of the voids is kept at a low value in the embedding aspect ratio exceeding generally three when the surface processing is performed by the O₂ plasma 23, 25 and the O₂ oxidation 27 in the diffusion furnace. This shows that the occurrence of the voids can be suppressed by the method of the Example even when the semiconductor element is miniaturized further and the interval between the gate electrodes is narrowed.

1. A method for manufacturing a semiconductor device, comprising the steps of:
(1) forming an insulating film composed of a thin silicon nitride film on a semiconductor substrate having at least a necessary element and a recessed part so as to cover the recessed part;
(2) modifying the surface of the insulating film; and
(3) forming a BPSG film as an interlayer insulation film on the insulating film.

2. The method for manufacturing the semiconductor device according to claim 1, wherein the insulating film is formed by a low pressure thermal CVD method at a temperature of 450° C. to 700° C.

3. The method for manufacturing the semiconductor device according to claim 1, wherein the insulating film is formed by a plasma CVD method.

4. The method for manufacturing the semiconductor device according to claim 1, wherein the surface of the insulating film is oxidized in an O₂ atmosphere to modify the surface of the insulating film in step (2).

5. The method for manufacturing the semiconductor device according to claim 1, wherein the surface of the insulating film is oxidized by a plasma processing to modify the surface of the insulating film in step (2).

6. The method for manufacturing the semiconductor device according to claim 1, wherein the surface of the insulating film is oxidized by a liquid chemical processing to modify the surface of the insulating film in the step (2).

7. The method for manufacturing the semiconductor device according to claim 1, wherein the BPSG film as the interlayer insulation film is formed by a TEOS-O₃-base CVD method.

8. The method for manufacturing the semiconductor device according to claim 1, further comprising the step of performing reflow of the BPSG film as the interlayer insulation film by a heat processing.

9. The method for manufacturing the semiconductor device according to claim 8, wherein the heat processing is a furnace processing in an N₂ atmosphere under a temperature of 700° C. to 790° C.

10. The method for manufacturing the semiconductor device according to claim 8, wherein the heat processing is a furnace processing in a water vapor atmosphere under a temperature of 700° C. to 790° C.

11. The method for manufacturing the semiconductor device according to claim 1, wherein the surface of the insulating film is oxidized in an 03 atmosphere to modify the surface of the insulating film in step (2).
